(19) United States
(12) Patent Application Publication
(10) Pub. No.: US 2013/0221341 A1
(43) Pub. Date: Aug. 29, 2013

(54) PHOTOELECTRIC CONVERSION DEVICE, AND PROCESS FOR MANUFACTURING PHOTOELECTRIC CONVERSION DEVICE

(71) Applicants: Hiroyuki Iwabuchi, Sodegaura-shi (JP); Chishio Hosokawa, Sodegaura-shi (JP)

(72) Inventors: Hiroyuki Iwabuchi, Sodegaura-shi (JP); Chishio Hosokawa, Sodegaura-shi (JP)

(73) Assignee: IDEMITSU KOSACO., LTD., Tokyo (JP)

(21) Appl. No.: 13/882,000

(22) PCT Filed: Oct. 21, 2011
(86) PCT No.: PCT/JP11/74250

§ 371 Date: Apr. 26, 2013

(30) Foreign Application Priority Data
Oct. 26, 2010 (JP) 2010-240120

(51) Int. Cl. H01L 51/52; H01L 51/00; H01L 51/44

(52) U.S. Cl. CPC H01L 51/5253; H01L 51/448; H01L 51/0001
USPC 257/40; 438/82; 438/46

(57) ABSTRACT

A photoelectric conversion device includes a first substrate, a first electrode, an organic layer, a second electrode and a second substrate that are provided in this order. An auxiliary electrode is interposed between the first electrode and the organic layer. When the photoelectric conversion device is seen in a cross section taken in a thickness direction of the first substrate, a thickness of the auxiliary electrode is greater than a thickness of the organic layer.

### TECHNICAL FIELD

The present invention relates to a photoelectric conversion device and a production method of the photoelectric conversion device.

### BACKGROUND ART

Photoelectric conversion devices having an organic compound layer disposed between a pair of electrodes provided on substrates have been proposed. Examples of the photoelectric conversion devices include organic electroluminescence devices (referred to as an organic EL device hereinafter) and organic thin-film solar cell elements. The organic EL device is an element for converting electricity to light. The organic thin-film solar cell element is an element for converting light into electricity.

Performance (e.g. element lifetime) of such a photoelectric conversion element is greatly influenced by water and air. Thus, a sealing structure for protecting the photoelectric conversion element from water and air is of great importance and various sealing structures have been studied.

An example of the typical sealing structure includes a sealing substrate attached to a glass substrate in order to seal the organic EL device provided on the glass substrate. The substrates are mutually attached to seal the organic EL device, whereby the organic EL device is kept from exposing to an ambient air and thus is kept from being degraded. With such a sealing structure, the glass substrate and the sealing substrate are sometimes in contact with each other due to an air pressure change or warpage of the substrate, so that the organic EL device provided on the glass substrate may be electrically shorted being sandwiched between the substrates. In order to avoid such a short-circuit, a recess is formed on at least one of the sealing substrate and the glass substrate (also referred to providing a counter sinking) to accommodate the organic EL device in the recess, so as to avoid the contact between the sealing substrate and the organic EL device.

For instance, Patent Literature 1 discloses an organic electroluminescent apparatus in which an organic EL device is sealed with a sealing can having a recess. The organic electroluminescent apparatus is also used for a lighting system. The organic electroluminescent apparatus includes a transparent electrode provided on a transparent glass substrate. An auxiliary electrode with a predetermined pattern is provided on the transparent electrode. The auxiliary electrode is covered with an insulating layer of a laminate structure. An organic EL layer is formed on the transparent electrode. An opposing electrode is provided to cover the insulating layer and the organic EL layer. The sealing can and the transparent glass substrate are bonded via an adhesive at an outer periphery of the transparent glass substrate and the organic EL device is accommodated in the recess, thereby keeping the sealing can from contacting the opposing electrode.

Patent Literature 2 discloses an electroluminescent panel that protects an emitting region from degradation due to external moisture or oxygen with a protection unit including a first protection film and a second protection film. The electroluminescent panel is used for a light source of an illuminating unit. The electroluminescent panel includes: a substrate; a first electrode provided on the substrate; an auxiliary electrode formed on the first electrode; an emitting layer formed on the first electrode and the auxiliary electrode to define the emitting region; and a second electrode formed on the emitting layer. The protection unit includes the first protection film and the second protection film.

However, since the protection unit of the electroluminescent panel disclosed in Patent Literature 2 is provided by films, the electroluminescent panel is weak against an external impact. Thus, when the electroluminescent panel is used in a lighting system, a sealing structure is employed, in which sealing substrate provided with a recess is bonded to the substrate at an outer periphery of the substrate and the emitting region is accommodated in the recess so as to keep the sealing substrate from contacting the second electrode.

As described above, since a sealing substrate or a sealing can provided with a recess is used in typical sealing structures, the sealing substrate or the sealing can is bonded to the to-be-bonded substrate in the proximity of the outer periphery of the to-be-bonded substrate, at which the sealing substrate and the like are supported. Accordingly, since it is not necessary to provide an independent support member for supporting the sealing substrate and the sealing can, a non-emitting portion due to the presence of the supporting member is not formed. In addition, when the photoelectric conversion device is produced, the sealing substrate and the like are kept from contacting the organic EL device and the like.

Especially, when the organic EL device is to be used as a light source of a lighting system as in the organic electroluminescent apparatus disclosed in Patent Literature 1 and the electroluminescent panel disclosed in Patent Literature 2, the electrode and the emitting layer are provided on a substantially entire surface of the substrate to enlarge the area of the emitting portion. The auxiliary electrode is provided on the transparent electrode or the first electrode in order to reduce unevenness in emission of the organic EL device. The region on which the auxiliary electrode is provided defines the non-emitting portion. Accordingly, in order to avoid further increase in the area of the non-emitting portion, a sealing structure requiring an independent support member is not used. Thus, the sealing structure using the sealing substrate and the like provided with a recess has come to be popularly used.

Similarly, a photoelectric conversion element in a form of an organic thin-film solar cell element also usually employs a sealing structure using a sealing substrate and the like provided with a recess in order to enlarge an area of a light receiver.

### CITATION LIST

### Patent Literatures

Patent Literature 1: JP-A-2008-10243
Patent Literature 2: JP-A-2008-103305

### SUMMARY OF THE INVENTION

### Problems to be Solved by the Invention

However, in order to provide a recess capable of accommodating a photoelectric conversion element, the thickness of the sealing substrate or the sealing can disclosed in Patent Literature 1 has to be increased. Accordingly, the thickness of the photoelectric conversion device cannot be significantly reduced in the sealing structure using the sealing substrate or the sealing can provided with the recess.

In addition, a high processing cost is required for providing the recess.

An object of the invention is to provide a photoelectric conversion device that is adapted to reduce the thickness thereof and can be inexpensively produced, and a production method of the photoelectric conversion device.

### Means for Solving the Problems

A photoelectric conversion device according to an aspect of the invention includes: a first substrate; a first electrode; an organic layer; a second electrode; a second substrate, the first substrate, the first electrode, the organic layer, the second electrode and the second substrate being layered in this order; and an auxiliary electrode interposed between the first electrode and the organic layer, in which a thickness of the auxiliary electrode is greater than a thickness of the organic layer in a cross section of the photoelectric conversion device taken in a thickness direction of the first substrate.

According to the above aspect of the invention, the thickness of the auxiliary electrode interposed between the first electrode and the organic layer is greater than the thickness of the organic layer in the cross section of the photoelectric conversion device taken in the thickness direction of the first substrate. Accordingly, when the cross section is seen with the first substrate placed at a lower side and the second substrate placed at an upper side, the auxiliary electrode is bulged toward the second substrate and the organic layer and the second electrode at an area in which the auxiliary electrode is provided are bulged toward the second substrate in conformity with the shape of the auxiliary electrode. The second substrate can be supported by the bulged portion. In other words, since the auxiliary electrode is interposed between the first electrode and the organic layer, the auxiliary electrode not only serves as an auxiliary electrode but also as a spacer for keeping the distance between the first substrate and the second substrate.

Thus, the photoelectric conversion device according to the above aspect of the invention does not require a recess (e.g. a counter sinking in the related art) provided to the first substrate and/or second substrate. Thus, the photoelectric conversion device can reduce the thickness thereof and can be inexpensively produced as compared to a typical sealing structure.

Since the thickness can be reduced as described above, the photoelectric conversion device according to the above aspect of the invention is also suitable for a flexible illumination using a photoelectric conversion element in a form of an organic EL device.

In the photoelectric conversion device according to the above aspect of the invention, it is preferable that the second electrode is in contact with the second substrate.

According to the above arrangement, the organic layer and the second substrate is interposed between the auxiliary electrode and the second electrode in this order, and the second electrode and the second substrate are in contact with each other. Accordingly, the second substrate is supported by the auxiliary electrode via the organic layer and the second electrode so that the distance between the first substrate and the second substrate is maintained. Further, when the first substrate and the second substrate are adhered, since the second substrate is supported by the second electrode, the adhesion process can be facilitated while keeping the distance between the first substrate and the second substrate.

In the photoelectric conversion device according to the above aspect of the invention, it is preferable that a sealing member for sealing the organic layer is interposed between the first substrate and the second substrate along outer peripheries of the first substrate and the second substrate, and the thickness of the auxiliary electrode and a thickness of the sealing member satisfies a formula (I) as follows.

0.2X<Y<5X (1)

In the above formula (I), Y [μm] represents the thickness of the auxiliary electrode and X [μm] represents the thickness of the sealing member.

According to the above arrangement, since the thickness Y of the auxiliary electrode and the thickness X of the sealing member satisfy the relationship represented by the above formula (I), even when the first substrate and/or the second substrate is flexed or warped, the distance between the first substrate and the second substrate can be reliably maintained.

In the photoelectric conversion device according to the above aspect of the invention, it is preferable that the thickness of the auxiliary electrode is in a range from 0.5 μm to 30 μm.

According to the above arrangement, since the thickness Y of the auxiliary electrode is in a range from 0.5 μm to 30 μm, even when the first substrate and/or the second substrate is flexed or warped, the distance between the first substrate and the second substrate can be reliably maintained.

In the photoelectric conversion device according to the above aspect of the invention, it is preferable that the sealing member is made of an insulative material.

According to the above arrangement, since the sealing member is made of an insulative material, the short circuit of the first and the second electrodes can be avoided.

In the photoelectric conversion device according to the above aspect of the invention, it is preferable that an area interposed between the first electrode and the second electrode with the auxiliary electrode being not disposed defines an emitting portion in which the organic layer is disposed, and the second electrode is spaced apart from the second substrate at the emitting portion.

According to the above arrangement, since only the organic layer is interposed between the first electrode and the second electrode at the area in which the auxiliary electrode is not disposed, the area defines the emitting portion. In the emitting portion, since the second electrode is spaced apart from the second substrate, the auxiliary electrode reliably serves as a spacer, thereby keeping the second substrate from contacting the second electrode at the emitting portion. Thus, the second electrode and the organic layer can be kept from being damaged.

In the photoelectric conversion device according to the above aspect of the invention, it is preferable that a heat-radiation member is interposed between the second electrode and the second substrate at the emitting portion.

According to the above arrangement, the unnecessary heat generated by the photoelectric conversion element can be efficiently transmitted to the second substrate via the heat-radiation member.

In the photoelectric conversion device according to the above aspect of the invention, it is preferable that the auxiliary electrode defines a frame shape surrounding the emitting portion when the photoelectric conversion device is seen facing a surface of the first substrate.

According to the above arrangement, since the auxiliary electrode defines the frame shape surrounding the emitting portion, when the heat-radiation member is interposed between the second electrode and the second substrate at the emitting portion, it does not occur that the heat-radiation member is disposed at the bonding portion between the first substrate and the second substrate to keep the first substrate from being bonded with the second substrate and the heat-radiation member is spread out of the photoelectric conversion device.

Further, when the heat-radiation member is fluid, the heat-radiation member is kept within the frame and is kept from flowing out of the frame. In other words, since the auxiliary electrode of which thickness is greater than that of the organic layer is provided in a frame shape, the auxiliary electrode serves as a bank for the fluid heat-radiation member.

Thus, it does not occur that the heat-radiation member flows to the bonding portion between the first substrate and the second substrate and to keep the first substrate and the second substrate from being bonded or the heat-radiation member further flows outside the photoelectric conversion device.

In the photoelectric conversion device according to the above aspect of the invention, it is preferable that the auxiliary electrode defines a shape surrounding the emitting portion with a part thereof being opened when the photoelectric conversion device is seen facing a surface of the first substrate.

According to the above arrangement, the auxiliary electrode defines a pattern surrounding the emitting portion with a part thereof being opened. Accordingly, even if the second electrode is disconnected along the pattern of the auxiliary electrode while the photoelectric conversion device is used for an application requiring flexibility and is repeatedly bent, an open portion is left on the second electrode corresponding to the partially opened pattern of the auxiliary electrode. In other words, a closed area is not formed on the second electrode due to the presence of the disconnected portion but an electrically connected portion remains. Thus, according to the above arrangement, even when the second electrode is disconnected, an electrical conduction can be ensured through the open portion, so that a formation of a non-conductive portion on the second electrode can be avoided. For instance, when the photoelectric conversion element is an organic EL device, a non-emitting portion is not formed.

On the other hand, when the pattern of the auxiliary electrode defines a frame shape without forming the open portion, the second electrode may be disconnected along the frame pattern of the auxiliary electrode after the repeated bending process as mentioned above. When the second electrode is disconnected in a frame shape, a closed area is formed on the second electrode due to the presence of the disconnected portion and an open portion does not remain. In other words, a non-electrically-connected portion is formed on the second electrode. Thus, an electric current is not applied to an interior of the frame corresponding to the frame-shaped disconnected portion of the second electrode. For instance, when the photoelectric conversion element is an organic EL device, the organic layer at an area corresponding to the interior of the frame of the second electrode does not emit light.

In the photoelectric conversion device according to the above aspect of the invention, it is preferable that an electrical conduction is established between the auxiliary electrode and the first electrode while the auxiliary electrode is electrically insulated from the organic layer.

According to the above arrangement, while the auxiliary electrode is electrically conducted with the first electrode, the auxiliary electrode and the organic layer are electrically insulated. Accordingly, when the photoelectric conversion device is an organic EL device, linear light emission of the portion near the frame portion of the auxiliary electrode can be avoided and the emitting portion can emit light in a sheet shape. In addition, the auxiliary electrode and the second electrode can be kept from being short-circuited.

In the photoelectric conversion device according to the above aspect of the invention, it is preferable that an insulative portion is interposed between the auxiliary electrode and the organic layer.

According to the above arrangement, the insulative portion interposed between the auxiliary electrode and the organic layer electrically insulates the auxiliary electrode and the organic layer. Accordingly, when the photoelectric conversion device is an organic EL device, similarly to the above, linear light emission of the portion near the frame portion of the auxiliary electrode can be avoided and the emitting portion can emit light in a sheet shape. In addition, the auxiliary electrode and the second electrode can be kept from being short-circuited.

In the photoelectric conversion device according to the above aspect of the invention, it is preferable that the insulative portion contains polyimide.

According to the above arrangement, since the insulative portion contains polyimide, the strength and heat resistance of the insulative portion are enhanced. Consequently, since the insulative portion becomes less likely to be damaged or degraded, the electrical conduction between the auxiliary electrode and the organic layer can be further reliably avoided.

In the photoelectric conversion device according to the above aspect of the invention, it is preferable that the auxiliary electrode contains at least one of silver, gold, tungsten and neodymium, and a resin.

According to the above arrangement, since the auxiliary electrode contains at least one of silver, gold, tungsten and neodymium, and a resin, the material for forming the auxiliary electrode can be provided in a form of a paste. Thus, the thickness of the auxiliary electrode can be easily made greater than the thickness of the organic layer.

In the photoelectric conversion device according to the above aspect of the invention, it is preferable that the first substrate is light-transmissive, and the first electrode is transparent.

According to the above arrangement, since the first substrate is light-transmissive and the first electrode is transparent, light can be efficiently extracted through or received from the first substrate.

In the photoelectric conversion device according to the above aspect of the invention, it is preferable that the second substrate is made of metal.

According to the above arrangement, since the second substrate is made of metal, the electrical conduction to the second electrode can be ensured. For instance, even when a part of the second electrode is disconnected, an electrical conduction can be ensured through the second substrate.

Further, when the second electrode is a transparent electrode, the second substrate can be used as a light reflector.

A production method of a photoelectric conversion device according to another aspect of the invention is for producing the photoelectric conversion device including: a first substrate; a first electrode; an organic layer; a second electrode; and a second substrate, the first substrate, the first electrode, the organic layer, the second electrode and the second substrate being layered in this order, the method including: forming the first electrode on one surface of the first substrate; forming the auxiliary electrode on the first electrode; forming the organic layer on the first electrode and the auxiliary electrode; forming the second electrode on the organic layer; and after the second electrode is formed, attaching and bonding the first substrate and the second substrate, in which a thickness of the auxiliary electrode is formed greater than a thickness of the organic layer in a cross section of the photoelectric conversion device taken in a thickness direction of the first substrate.

According to the above aspect of the invention, since the thickness of the auxiliary electrode is greater than the thickness of the organic layer, the auxiliary electrode not only serves as a mere auxiliary electrode but also as a spacer for keeping the distance between the first substrate and the second substrate. Thus, when the first substrate and the second substrate are to be bonded, the bonding can be performed while keeping the distance between the first substrate and the second substrate.

In addition, since it is not necessary to provide a recess (e.g. counter sinking) on the first substrate and the second substrate, the thickness of the photoelectric conversion device can be reduced and the photoelectric conversion device can be inexpensively produced.

In the production method of the photoelectric conversion device according to the invention, it is preferable that, in the forming of the auxiliary electrode, the auxiliary electrode is formed in a frame shape seen in a direction facing a surface of the first substrate, and, after forming the second electrode and before attaching and bonding the first substrate and the second substrate, a fluid heat-radiation member is injected into the frame defined by the auxiliary electrode.

According to the above arrangement, since the auxiliary electrode is provided in a frame shape, the heat-radiation member is kept from being flowed out of the frame when the fluid heat-radiation member is injected into the frame. In other words, since the auxiliary electrode of which thickness is greater than that of the organic layer is provided in a frame shape, the auxiliary electrode serves as a bank for the heat-radiation member.

Accordingly, the heat-radiation member can be easily injected. In addition, the heat-radiation member is kept from flowing to the bonding portion between the first substrate and the second substrate and from further flowing out of the photoelectric conversion device.

In the production method of the photoelectric conversion device according to the above aspect of the invention, it is preferable that, after forming the auxiliary electrode and before forming the organic layer, an insulative portion is formed on the auxiliary electrode, and the insulative portion is interposed between the organic layer and the auxiliary electrode.

According to the above arrangement, the insulative portion interposed between the organic layer and the auxiliary electrode electrically insulates the organic layer and the auxiliary electrode. Accordingly, when the photoelectric conversion device is an organic EL device, linear light emission of the portion near the frame portion of the auxiliary electrode can be avoided and the emitting portion can emit light in a sheet shape.

Further, the photoelectric conversion device produced according to the above aspect of the invention has the auxiliary electrode of which thickness is greater than the thickness of the organic layer, a material in a form of a paste containing metal (e.g. silver paste) and a resin is used for forming the auxiliary electrode for easily increasing the thickness. After forming the auxiliary electrode with the use of the paste material, when the organic layer is to be formed under a pressure-reduced atmosphere (e.g. evaporation method and sputtering) without forming the insulative portion, a gas is emitted from the paste material so that impurities may be mixed into the organic layer.

However, according to the above arrangement, since the insulative portion is formed on the auxiliary electrode, the surface of the auxiliary electrode can be covered with the insulative portion. Thus, the gas emission from the auxiliary electrode can be avoided when the organic layer is formed, thereby preventing impurities from mixing into the organic layer.

### BRIEF DESCRIPTION OF DRAWINGS

FIG. 1 is a cross section in a substrate-thickness direction showing a photoelectric conversion device according to a first exemplary embodiment of the invention.

FIG. 2A is a perspective view showing a first production step of the photoelectric conversion device according to the first exemplary embodiment.

FIG. 2B is a cross section showing the first production step of the photoelectric conversion device according to the first exemplary embodiment.

FIG. 3A is a perspective view showing a second production step of the photoelectric conversion device according to the first exemplary embodiment.

FIG. 3B is a cross section showing the second production step of the photoelectric conversion device according to the first exemplary embodiment.

FIG. 4A is a perspective view showing a third production step of the photoelectric conversion device according to the first exemplary embodiment.

FIG. 4B is a cross section showing the third production step of the photoelectric conversion device according to the first exemplary embodiment.

FIG. 5A is a perspective view showing a fourth production step of the photoelectric conversion device according to the first exemplary embodiment.

FIG. 5B is a cross section showing the fourth production step of the photoelectric conversion device according to the first exemplary embodiment.

FIG. 6 is a cross section showing a fifth production step of the photoelectric conversion device according to the first exemplary embodiment.

FIG. 7 is a cross section showing a sixth production step of the photoelectric conversion device according to the first exemplary embodiment.

FIG. 8 is a cross section showing a seventh production step of the photoelectric conversion device according to the first exemplary embodiment.

FIG. 9 is a cross section showing an eighth production step of the photoelectric conversion device according to the first exemplary embodiment.

FIG. 10 is a cross section in a substrate-thickness direction showing a photoelectric conversion device according to a second exemplary embodiment of the invention.

FIG. 11 is a perspective view showing an auxiliary electrode pattern of a photoelectric conversion device according to a third exemplary embodiment of the invention.

FIG. 12 is a perspective view showing the auxiliary electrode pattern according to the third exemplary embodiment of the invention on which an insulative portion is provided.

FIG. 13 is a perspective view showing a first modification of the auxiliary electrode pattern of the invention.

FIG. 14 is a perspective view showing a second modification of the auxiliary electrode pattern of the invention.

### EXEMPLARY EMBODIMENTS

### First Exemplary Embodiment

A first exemplary embodiment of the invention will be described below with reference to the attached drawings.

### Overall Structure of Photoelectric Conversion Device

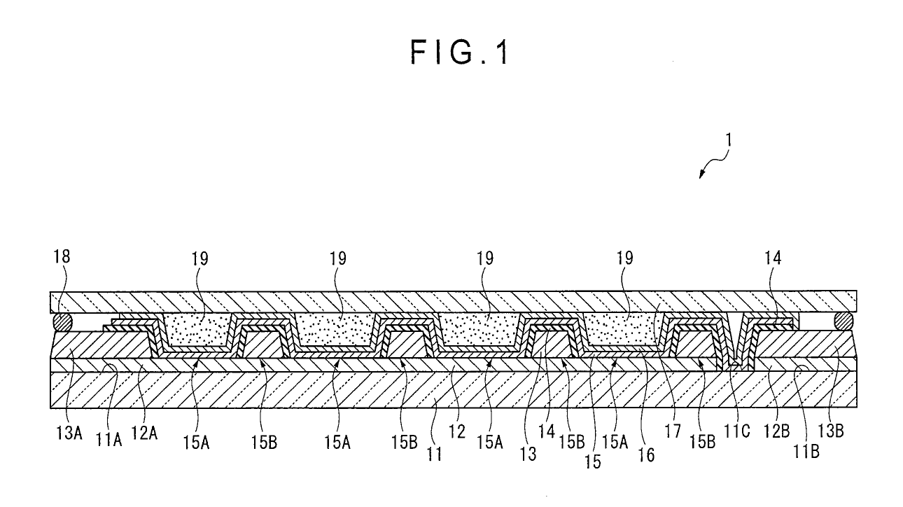

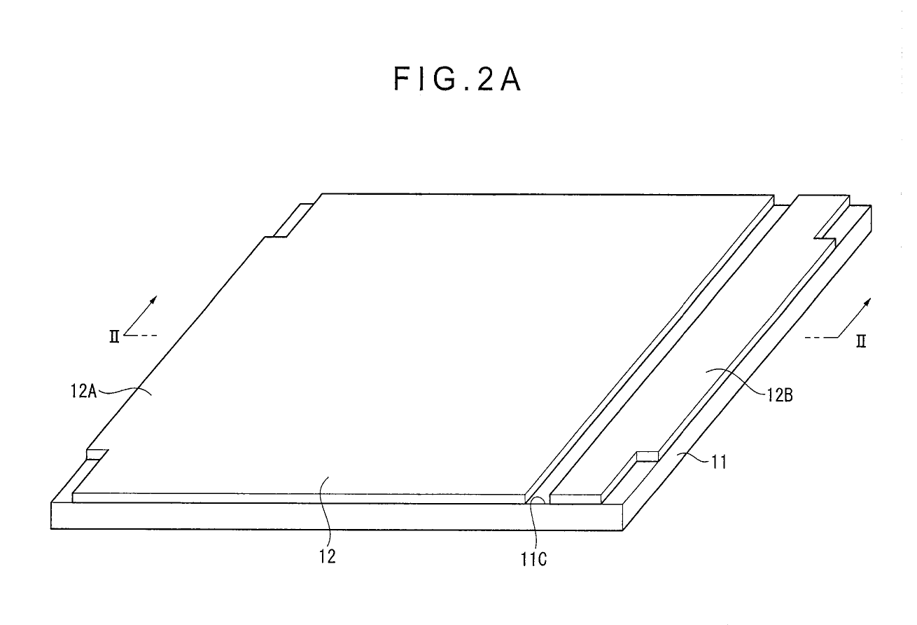

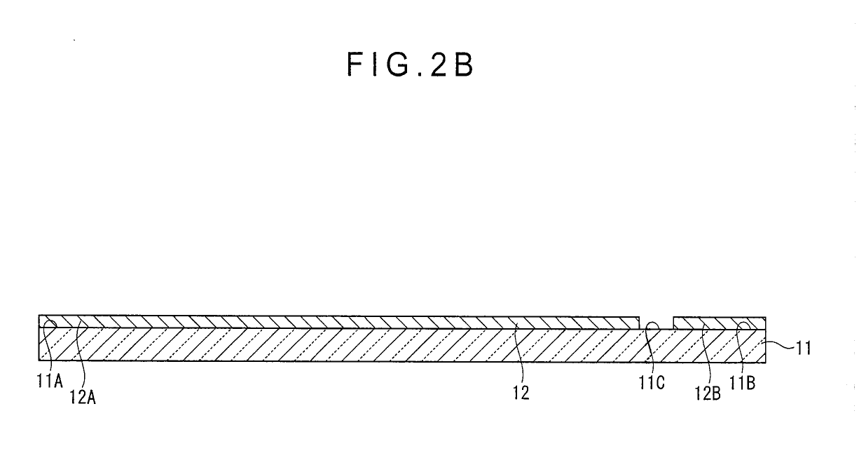

FIG. 1 is a cross section in a substrate-thickness direction showing a photoelectric conversion device 1 according to the first exemplary embodiment of the invention. FIGS. 2A to 9 are perspective views or cross sectional views showing production steps of the photoelectric conversion device 1.

The photoelectric conversion device 1 includes a first substrate 11, a first electrode 12, an organic layer 15, a second electrode 16 and a second substrate 17 arranged in this order. The first electrode 12, the organic layer 15 and the second electrode 16 provides a photoelectric conversion element. In the first exemplary embodiment, the photoelectric conversion element in a form of an organic EL device will be described. An auxiliary electrode 13 is disposed between the first electrode 12 and the organic layer 15. An insulative portion 14 is interposed between the auxiliary electrode 13 and the organic layer 15. A sealing member 18 for sealing the organic layer 15 is interposed between the first substrate 11 and the second substrate 17 along outer peripheries thereof. A heat-radiation member 19 is provided between the second electrode 16 and the second substrate 17.

It should be noted that up (top), down (bottom), right and left directions in the description of the first exemplary embodiment refer to directions shown in the cross section of FIG. 1 in which the first substrate 11 is laid on the bottom side and the second substrate 17 is laid on the top side.

The cross section shown in FIG. 2B is the cross section of the first substrate 11 cut along II-II line in FIG. 2A and seen in the direction of the arrows. Similarly, the cross sections of FIGS. 1, 3B, 4B, 5B and 6 to 9 are cross sections of the first substrate 11 cut at the same position as in FIG. 2B and seen in the direction of the arrows.

### First Substrate

The first substrate 11 is a flat smooth plate member for supporting the first electrode 12 and the like.

In the first exemplary embodiment, the first substrate 11 is provided by a light-transmissive substrate and the light from the organic EL device is extracted through the first substrate 11. Thus, a visible light transmittance (i.e. the transmittance of a light in a visible region (400 nm to 700 nm)) of the first substrate 11 is preferably 50% or more. The first substrate 11 is exemplarily provided by a sheet glass, a polymer plate or the like. For the sheet glass, such materials as soda-lime glass, barium/strontium-containing glass, lead glass, aluminosilicate glass, borosilicate glass, barium borosilicate glass, quartz and the like can be used. For the polymer plate, materials such as polycarbonate resins, acryl resins, polyethylene terephthalate resins, polyether sulfide resins and polysulfone resins can be used. When the photoelectric conversion device 1 is used for an application requiring flexibility, the first substrate 11 is preferably made of a flexible material (e.g. polymer plate).

Further, when a plurality of the photoelectric conversion devices 1 are adjacently disposed to provide a light source of a lighting system, the first substrate 11 is provided by a plate material of, for instance, vertical length of approximately 80 mm to 100 mm, horizontal length of approximately 80 mm to 100 mm and thickness in a range from 0.1 mm to 5 mm. A plurality of the first substrates 11 may be cut out from a large-size substrate material.

Right and left ends of the first substrate 11 each define a connecting portion 11A on which a leading electrode 12A for electrical output from the first electrode 12 is disposed at an upper portion and a connecting portion 11B on which a leading electrode 12B for electrical output from the second electrode 16 is disposed at an upper portion.

### First Electrode

The first electrode 12 serves as an anode of the organic EL device for injecting holes to the organic layer 15. The first electrode 12 preferably has a work function of 4.5 eV or more in terms of efficiency.

The first electrode 12 is formed on the first substrate 11. At this time, the leading electrode 12A for electrical output from the first electrode 12 (anode) is provided on the connecting portion 11A of the first substrate 11 in a manner continuous with the first electrode 12. The leading electrode 12B for electrical output from the second electrode 16 (cathode) is provided on the connecting portion 11B of the first substrate 11 with a groove 11C interposed. The leading electrode 12B is not electrically connected with the first electrode 12.

Specific examples the material used for the first electrode 12 include indium-tin oxide (ITO), tin oxide (NESA), indium-zinc oxide, gold, silver, platinum and copper.

In the photoelectric conversion device 1, in order to extract the emitted light through the organic layer 15 from the first electrode 12, it is preferable that the visible light transmittance of the first electrode 12 is 10% or more. Further, the sheet resistance of the first electrode 12 is preferably several hundreds Ω/□ (Ω/sq. ohm per square) or less. Though depending on the material to be used, the thickness of the first electrode 12 is typically selected within a range from 10 nm to 1 μm, preferably in a range from 10 nm to 200 nm.

### Auxiliary Electrode

The auxiliary electrode 13 prevents a voltage reduction due to an electric resistance of the transparent electrode material used for the first electrode 12, applies voltage to the first electrode 12 and reduces fluctuation in voltage supplied to the first electrode 12 depending on the location on the first substrate 11. The auxiliary electrode 13 and the first electrode 12 are mutually electrically connected. The auxiliary electrode 13 and the organic layer 15 are electrically insulated by the insulative portion 14 detailed later.

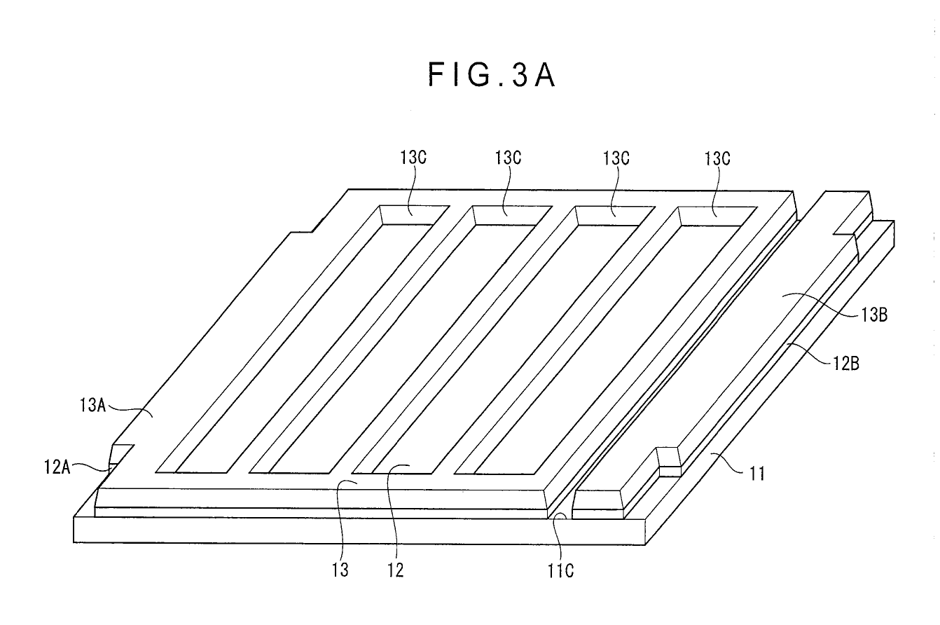

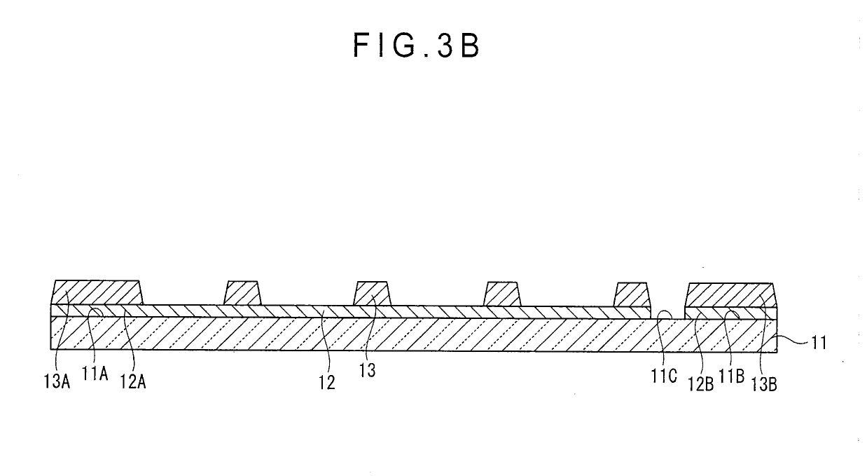

As shown in FIGS. 1, 3A and 3B, the auxiliary electrode 13 is provided on the first electrode 12 to form a plurality of lines spaced apart from each other. The auxiliary electrode 13 is provided in a frame shape in which four openings 13C are defined. The first electrode 12 is exposed through the openings 13C.

Further, a leading-assist electrode 13A for electrical output from the first electrode 12 is provided on the leading electrode 12A. Similarly, a leading-assist electrode 13B for electrical output from the second electrode 16 is provided on the leading electrode 12B. The leading-assist electrode 13A is continuous with the auxiliary electrode 13, whereas the leading-assist electrode 13B is discontinuous with the auxiliary electrode 13 with the groove 11C interposed therebetween. The leading-assist electrode 13B is not electrically connected with the auxiliary electrode 13 and the first electrode 12.

The shape (e.g. the number of the frames and size) of the auxiliary electrode 13 is not limited to that illustrated in FIG. 3A but may be designed as desired as long as all of the frames of the auxiliary electrode 13 are closed relative to the surface of the second electrode 16. In other words, it is only required for the auxiliary electrode 13 to be formed in a “bank.”

The thickness of the auxiliary electrode 13 is larger than the thickness of the organic layer 15 as seen in the cross section of FIG. 1.

Supposing that the thickness of the auxiliary electrode 13 is Y [μm] and the thickness of the sealing member 18 (detailed later) is X[μm], it is preferable that X and Y satisfy the above formula (I). The thickness of the auxiliary electrode 13 is preferably in a range from 1 μm to 50 μm.

The width of the auxiliary electrode 13 and the gap between the auxiliary electrodes 13 are appropriately determined depending on the device structure, electroconductivity of the first electrode 12 and the shape and number of the frames of the auxiliary electrode 13. However, since the area on which the auxiliary electrode 13 is formed does not emit light when seen in the direction facing the surface of the first substrate 11 (i.e. non-emitting portion 15B), in order to enlarge a light-emitting area, the width of the auxiliary electrode 13 is preferably as small as possible and the interval between the lines of the auxiliary electrode 13 is as wide as possible.

The resistivity of the auxiliary electrode 13 is preferably 10⁻⁴ Ωcm or less.

As described above, the auxiliary electrode 13 is provided between the first electrode 12 and the organic layer 15 and the thickness of the auxiliary electrode 13 is greater than the thickness of the organic layer 15. Thus, as shown in the cross section in FIG. 1, the portion corresponding to the auxiliary electrode 13 is raised toward the second substrate 17. The shapes of the organic layer 15 and the second electrode 16 conform to the shape of the auxiliary electrode 13. The second electrode 16 is in contact with the second substrate 17 at the portion corresponding to the auxiliary electrode 13. Thus, the auxiliary electrode 13 also serves as a spacer for supporting the second substrate 17 via the second electrode 16 and the organic layer 15 to keep the distance between the first substrate 11 and the second substrate 17.

The areas at which the organic layer 15 is disposed and the auxiliary electrode 13 is not interposed between the first electrode 12 and the second electrode 16 emit light when a voltage is applied between the first electrode 12 and the second electrode 16 and the electric current flows in the organic layer 15. In other words, the area in which the auxiliary electrode 13 is not disposed but the organic layer 15 is disposed defines an emitting portion 15A. The area at which the auxiliary electrode 13 and the organic layer 15 are disposed between the first electrode 12 and the second electrode 16 does not emit light since the electric current does not flow due to the presence of the insulative portion 14 even when a voltage is applied between the first electrode 12 and the second electrode 16. In other words, the area in which the auxiliary electrode 13 and the organic layer 15 are disposed defines the non-emitting portion 15B.

Known electrode materials are used for the auxiliary electrode 13. Examples of the electrode materials include metal and alloy. The metal preferably includes, for instance, at least one of silver (Ag), aluminum (Al), gold (Au), tungsten (W) and neodymium (Nd).

A paste material containing metal or alloy and resin material is preferably used for the auxiliary electrode 13 so that the thickness of the auxiliary electrode 13 becomes larger than the thickness of the organic layer 15. The resin material serves as a binder. The rein material may be an acrylic resin, PET and the like. An organic solvent for adjusting viscosity may be added to turn the material into the paste form. The paste material is preferably a silver paste.

### Insulative Portion

The insulative portion 14 is interposed between the auxiliary electrode 13 and the organic layer 15 so that the auxiliary electrode 13 and the organic layer 15 are electrically insulated. In the above arrangement, the electrical connection between the auxiliary electrode 13 and the first electrode 12 are secured. The insulative portion 14 prevents the short-circuiting between the auxiliary electrode 13 and the second electrode 16. The organic layer 15 is interposed between the auxiliary electrode 13 and the second electrode 16 and the thickness of the organic layer 15 is typically 1 μm or less. The insulative portion 14 prevents the organic layer 15 from being damaged due to an external force applied from the second substrate 17 (described later) to the photoelectric conversion device 1 to keep the auxiliary electrode 13 and the second electrode 16 from being short-circuited.

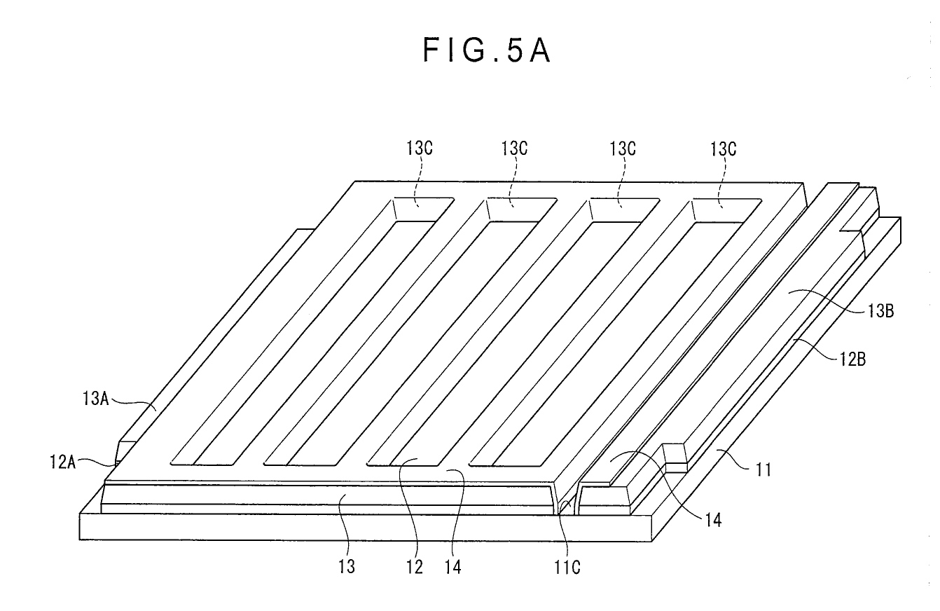

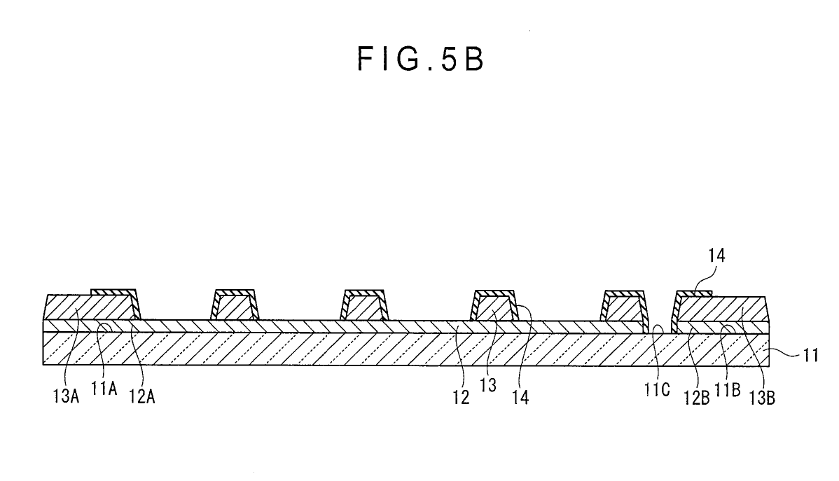

The insulative portion 14 is provided on the auxiliary electrode 13 to cover the auxiliary electrode 13. As shown in FIG. 5A, the first electrode 12 is exposed through the opening 13C. As shown in FIGS. 1 and 5B, the insulative portion 14 is provided on a part (upper surface and lateral surface) of the auxiliary electrode 13 that is not in contact with the first electrode 12, so as to keep the organic layer 15 from being in contact with the auxiliary electrode 13. As described above, since the first electrode 12 is exposed through the opening 13C, the organic layer 15 and the second electrode 16 are provided on the exposed first electrode 12. In other words, the exposed portion corresponds to the above-described portion that defines the emitting portion 15A.

The insulative portion 14 is provided so as not to entirely cover the upper surface of the leading-assist electrode 13A, i.e. provided to expose a part of the leading-assist electrode 13A. In other words, it is sufficient for the leading-assist electrode 13A to be exposed so as to allow an electrical output.

Further, the insulative portion 14 are discontinuous with the groove 11C interposed between the insulative portion 14 on the auxiliary electrode 13 and the insulative portion 14 on the leading-assist electrode 13B. The insulative portion 14 is provided so as not to entirely cover the upper surface of the leading-assist electrode 13B, i.e. provided to expose a part of the leading-assist electrode 13B. In other words, it is also sufficient for the leading-assist electrode 13B to be exposed so as to allow an electrical output.

Incidentally, when the resistance of the auxiliary electrode 13 is lower than that of the first electrode 12, the electric current is sometimes more concentrated at the portion corresponding to the auxiliary electrode 13 than the portion corresponding to the opening 13C. The insulative portion 14 keeps the portion corresponding to the auxiliary electrode 13 from emitting light at a high luminance to cause uneven luminance.

Further, when the auxiliary electrode 13 is provided by the paste material containing metal, alloy and resin material, emission gas from the solvent and resin material, moisture, atmospheric component and the like may be emitted from the auxiliary electrode 13. The insulative portion 14 keeps the gaseous components from damaging the organic layer 15.

The thickness of the insulative portion 14 is preferably in a range from 1 μm to 50 μm. With the above thickness range, the electrical connection between the auxiliary electrode 13 and the organic layer 15 and, consequently, direct injection of holes from the auxiliary electrode 13 to the organic layer 15 can be prevented.

The insulative portion 14 is provided by an electrically insulative material. Examples of the electrically insulative material include a photosensitive resin such as a photosensitive polyimide, light curing resin such as an acrylic resin, thermosetting resin and an organic material such as silicon oxide (SiO₂) and aluminum oxide (Al₂O₃). The photosensitive resin may be either a positive photosensitive resin or a negative photosensitive resin.

The insulative portion 14 may be provided with a material different from the auxiliary electrode 13 or, alternatively, may be provided by a surface treatment on the auxiliary electrode 13 to alter the electroconductive material forming the auxiliary electrode 13 into an insulative material (e.g. metal oxide film).

### Organic Layer

Since the photoelectric conversion device 1 is an organic EL device, the organic layer 15 is provided as a layer with a luminous function. The organic layer 15 refers to a layer having at least one layer provided by an organic compound. The organic layer 15 may contain an inorganic compound.

The organic layer 15 is provided on the auxiliary electrode 13 covered with the insulative portion 14 and on the first electrode 12 exposed through the opening 13C.

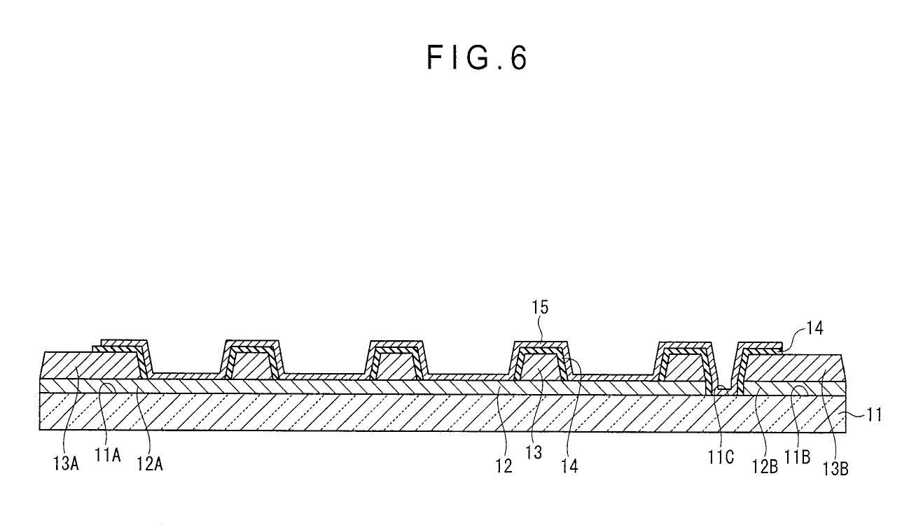

In order not to entirely cover the upper surfaces of the leading-assist electrode 13A and the leading-assist electrode 13B, the organic layer 15 is provided inside relative to the right and left ends of the insulative portion 14 as shown in FIG. 6 or, alternatively, up to the right and left ends of the insulative portion 14. As a result, the upper surfaces of the leading-assist electrode 13A and the leading-assist electrode 13B are exposed so as to allow an electrical output.

Further, the organic layer 15 continuously extends from the first electrode 12 to the leading electrode 12B through the groove 11C.

The organic layer 15 of the organic EL device of the photoelectric conversion device 1 includes at least one emitting layer. Thus, the organic layer 15 may be provided by, for instance, a single emitting layer or, alternatively, may be provided by a laminate of, for instance, a hole injecting layer, a hole transporting layer, an electron injecting layer and an electron transporting layer with the emitting layer being interposed.

The emitting layer, which is formed of known emitting material(s) used in typical organic EL device, provides a single-color emission (e.g. red, green, blue or yellow emission), or combined-color emission of red, green, blue and yellow emission (e.g., white-color emission). In forming the emitting layer, a doping method, according to which an emitting material (dopant) is doped to a host, has been known as a usable method. The emitting layer formed by the doping method can efficiently generate excitons from electric charges injected into the host. With the exciton energy generated by the excitons being transferred to the dopant, the dopant can emit light with a high efficiency.

The emitting layer may either be fluorescent or phosphorescent.

The materials for providing the hole injecting layer, hole transporting layer, electron injecting layer and electron transporting layer may be selected as desired from known materials used in typical organic EL devices.

### Second Electrode

The second electrode 16 serves as a cathode of the organic EL device for injecting electrons to the organic layer 15. The second electrode 16 preferably is made of a material having a small work function.

The second electrode 16 is formed on the organic layer 15.

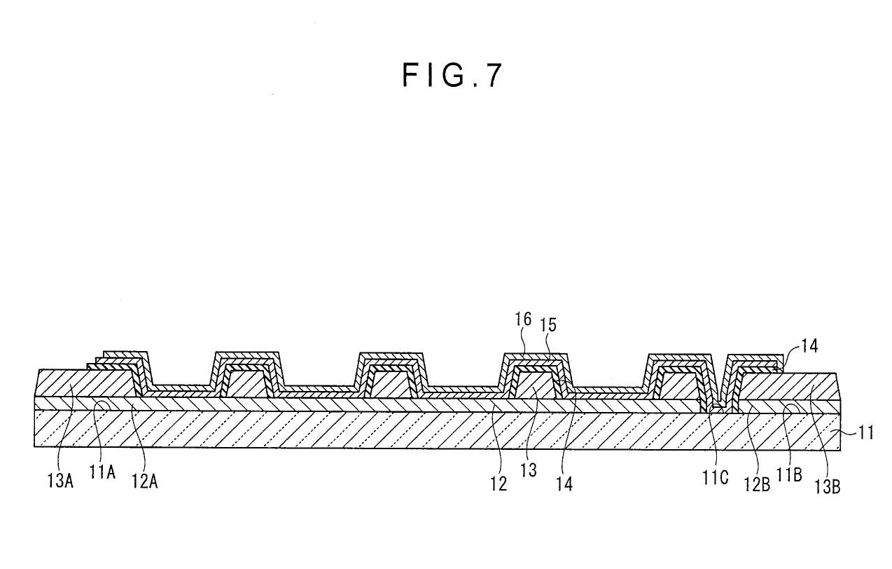

The second electrode 16 near the connecting portion 11A is provided inside the left ends of the insulative portion 14 and the organic layer 15 or, alternatively, up to the left end of the organic layer 15 as shown in FIG. 7 so that the second electrode 16 is not in contact with the leading-assist electrode 13A to be electrically connected.

On the other hand, as shown in FIG. 7, the second electrode 16 near the connecting portion 11B extends further outward relative to the right end of the insulative portion 14 to be in contact with the leading-assist electrode 13B to be electrically connected. However, the upper surface of the leading-assist electrode 13B is exposed to an extent to allow an electrical output.

Further, the second electrode 16 continuously extends from the first electrode 12 to the leading electrode 12B through the groove 11C.

The material used for the second electrode 16 is not specifically limited but the examples usable as the material include indium, aluminum, magnesium, silver, magnesium-indium alloy, magnesium-aluminum alloy, aluminum-lithium alloy, aluminum-scandium-lithium alloy and magnesium-silver alloy.

Alternatively, the light emission from the organic layer 15 may be extracted from the side of the second electrode 16. When the emitted light is extracted from the side of the second electrode 16, it is preferable that a transparent electrode material is used for the second electrode 16 and the visible light transmittance of the second electrode 16 is 10% or more. A metal or alloy is used for the first electrode 12 in the above arrangement. The sheet resistance of the second electrode 16 is preferably several hundreds Ω/□ (Ω/sq. ohm per square) or less.

Though depending on the material to be used, the thickness of the second electrode 16 is typically selected within a range from 10 nm to 1 um, preferably in a range from 50 nm to 200 nm.

### Second Substrate

The second substrate 17 is a flat smooth plate member to be bonded to the first substrate 11 with the use of the sealing member 18 (detailed later). The organic EL device in the photoelectric conversion device 1 includes the sealing member 18 for bonding and sealing the first substrate and the second substrate 17.

The second substrate 17 is supported by the frame-shaped auxiliary electrode 13 provided on the first electrode 12. As described above, the thickness of the auxiliary electrode 13 is larger than the thickness of the organic layer 15. As shown in FIG. 1, the auxiliary electrode 13 bulges toward the second substrate 17 and the organic layer 15 and the second electrode 16 at the portion corresponding to the area in which the auxiliary electrode 13 is formed conform to the shape of the auxiliary electrode 13 to be bulged toward the second substrate 17. The second substrate 17 and the second electrode 16 are contacted at the area in which the auxiliary electrode 13 is provided to support the second substrate 17.

The second substrate 17 is preferably a plate, a film or a foil member. Specifically, a sheet glass, a polymer plate, a polymer film, a metal plate and a metal foil and the like may be employed. Though the second substrate 17 is provided by a plate member in the first exemplary embodiment, the second substrate 17 may alternatively be provided by a sheet member or a film member. When the photoelectric conversion device 1 is used for an application requiring flexibility, the second substrate 17 is preferably made of a flexible material (e.g. a polymer plate and a polymer film).

Further, when a plurality of the photoelectric conversion devices 1 are adjacently disposed to provide a light source of a lighting system, the second substrate 17 is provided by a plate material of, for instance, vertical length of approximately 80 mm to 100 mm, horizontal length of approximately 80 mm to 100 mm and thickness in a range from 0.1 mm to 5 mm. When the thickness is than 0.1 mm or less, air permeability is increased to decrease the sealing performance.

A plurality of the second substrates 17 may be cut out from a large-size substrate material.

### Heat-Radiation Member

The heat-radiation member 19 serves for efficiently transmitting the heat generated by the organic EL device toward the second substrate 17.

The heat-radiation member 19 is provided at the emitting portion 15A between the second electrode 16 and the second substrate 17.

In the first exemplary embodiment, the heat-radiation member 19 has a fluidity and is injected to an inside of the opening 13C of the frame-shaped auxiliary electrode 13 so as not to be flowed out of the frame (see FIGS. 1, 3A, 3B and 8). The auxiliary electrode 13 also serves as a bank for keeping the heat-radiation member 19 from flowing toward the connecting portion 11A and the connecting portion 11B. Accordingly, all of the frames of the auxiliary electrode 13 of the photoelectric conversion device 1 are closed (i.e. not opened).

The injection amount of the heat-radiation member 19 is preferably determined so that the heat-radiation member 19 does not flow to the connecting portion 11A and the connecting portion 11B when the first substrate 11 and the second substrate 17 are attached. Further, considering heat transmission efficiency, the space defined between the second electrode 16 and the second substrate 17 when the first substrate 11 and the second substrate 17 are attached is preferably filled with the heat-radiation member 19 with no air being contained therein.

The heat-radiation member 19 is preferably provided by an inactive member with excellent heat conductivity (e.g. fluorinated oil).

### Sealing Member

The sealing member 18 bonds the first substrate 11 and the second substrate 17 to seal the organic layer 15.

The sealing member 18 is disposed along the outer peripheries of the first substrate 11 and the second substrate 17. The sealing member 18 is provided in a frame shape surrounding the organic layer 15. It should be noted that, as shown in FIG. 1, at the areas of the first substrate 11 on which the first electrode 12, the auxiliary electrode 13, the leading-assist electrode 13A and the leading-assist electrode 13B are formed, the sealing member 18 is not in direct contact with the first substrate 11 but is in contact with one of the first electrode 12, the auxiliary electrode 13, the leading-assist electrode 13A and the leading-assist electrode 13B to be bonded thereto. The sealing member 18 is in direct contact with the first substrate 11 in the rest of areas.

The width of the sealing member 18 (bonding width) is preferably narrow as long as a certain level of bonding strength between the first substrate 11 and the second substrate 17 can be ensured in order to provide the photoelectric conversion device 1 in a narrow bezel structure. For instance, when the substrates are made of a sheet glass member of 100 mm×100 mm×0.7 mm (height×width×thickness), it is especially preferable that the bonding width is in a range from 0.5 mm to 2 mm.

The sealing member 18 is preferably provided by an inorganic compound in terms of sealing performance, moisture resistance and bonding strength. A low-melting-point glass is preferable so as to make it possible to form the sealing member by a laser radiation. The “low-melting point” herein refers to a melting point of 650 degrees C. or lower. The melting point is preferably in a range from 300 degrees C. to 600 degrees C. Further, the low-melting-point glass preferably contains transient metal oxide, rare-earth oxide and the like that can be bonded to glass, metal and the like, more preferably the low-melting-point glass contains a granulated glass (a fritted glass). The granulated glass preferably contains, for instance, silicon oxide (SiO₂), boron oxide (B₂O₃) and aluminum oxide (Al₂O₃) as a main component. The sealing member 18 may alternatively be provided by a glass paste in which the granulated glass and a binder resin are mixed.

### Production Process of Organic EL Device

Next, a production process of the photoelectric conversion device will be described below with reference to the attached drawings.

### Production Step of First Substrate Component

Initially, as shown in FIGS. 2A and 2B, the first electrode 12 is formed on the first substrate 11. The leading electrode 12A is formed on the connecting portion 11A of the first substrate 11 and the leading electrode 12B is formed on the connecting portion 11B of the first substrate 11. At this time, the groove 11C is also formed. The first electrode 12, the leading electrode 12A and the leading electrode 12B are preferably simultaneously formed with the same material. In order to extract light through the first electrode 12, the first electrode 12 of the photoelectric conversion device 1 is provided by a transparent electrode material (e.g. ITO). In order to form the first electrode 12, a film may be formed by sputtering and patterned with photolithography process, a mask evaporation or the like.

Next, as shown in FIGS. 3A and 3B, the auxiliary electrode 13 is formed on the first electrode 12. The leading-assist electrode 13A is formed on the leading electrode 12A and the leading-assist electrode 13B is formed on the leading electrode 12B. At this time, the auxiliary electrode 13 is formed in a frame shape with four openings 13C. Further, the leading-assist electrode 13B is formed to be discontinuous with the auxiliary electrode 13 with the groove 11C interposed therebetween.

The auxiliary electrode 13, the leading-assist electrode 13A and the leading-assist electrode 13B are preferably simultaneously formed with the same material.

The auxiliary electrode 13, the leading-assist electrode 13A and the leading-assist electrode 13B may be formed by a known method including dry film-forming such as vacuum deposition, sputtering, plasma deposition and ion plating, and wet film-forming such as screen printing, ink jet printing, spin coating, dipping and flow coating. Since the thickness of the auxiliary electrode 13 of the photoelectric conversion device 1 is required to be large, a screen printing using a paste material containing metal, alloy and a resin material (e.g. silver paste) is preferable.

After the paste material for the auxiliary electrode 13 is applied by screen printing, the paste material is dried to form the auxiliary electrode 13, the leading-assist electrode 13A and the leading-assist electrode 13B.

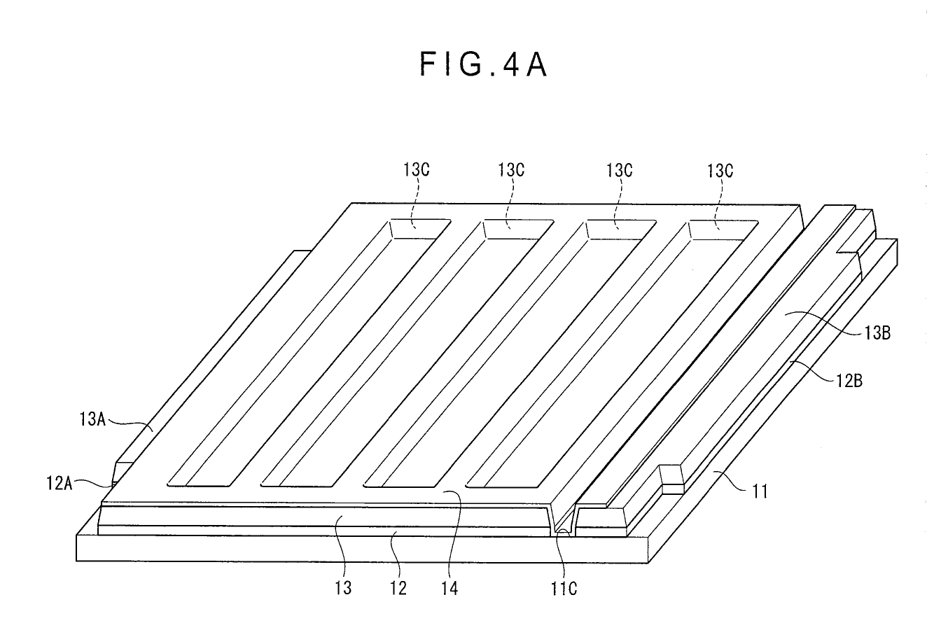

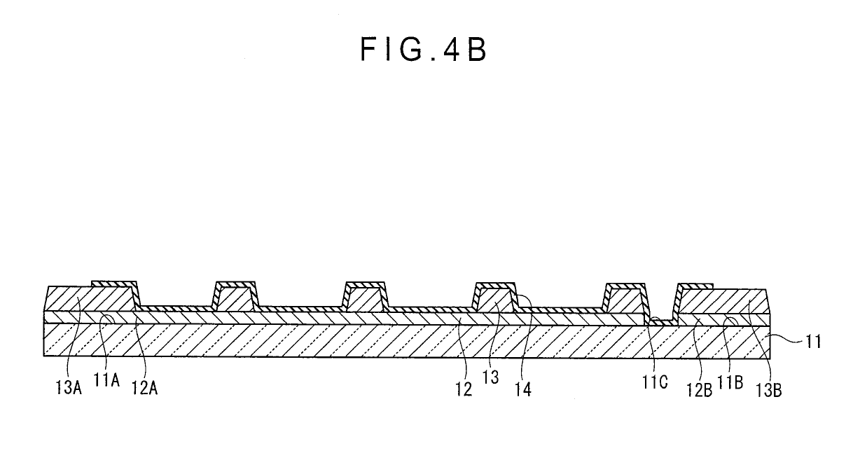

Subsequently, as shown in FIGS. 4A, 4B, 5A and 5B, the insulative portion 14 is formed on the auxiliary electrode 13. The insulative portion may be formed by a known wet film-forming such as screen printing, ink jet printing, spin coating, dipping and flow coating or a known dry film-forming such as mask deposition and mask sputtering. Herein, an instance in which the insulative portion is formed by wet film-forming with the use of positive photoresist material containing an electrically insulative resin will be described.

Initially, as shown in FIGS. 4A and 4B, an electrically insulative paste material for forming the insulative portion 14 is applied on the auxiliary electrode 13 in a wet film-forming. At this time, while the upper surface of the leading-assist electrode 13A and the upper surface of the leading-assist electrode 13B are not entirely covered with the electrically insulative material, the upper and lateral surfaces of the auxiliary electrode 13 are covered with the electrically insulative material. When the electrically insulative material is applied, the electrically insulative material may be applied on an inside of the opening 13C.

After the electrically insulative material is applied, light is irradiated on the electrically insulative material from the side of the first substrate 11 (exposure). At this time, though the light is irradiated to the electrically insulative material applied on the inside of the opening 13C and the groove 11C, the light is not irradiated on the electrically insulative material applied on the upper surface of the auxiliary electrode 13. Thus, when being subjected to image development with a developer after the exposure, a part of the electrically insulative material applied to the inside of the opening 13C and the groove 11C are removed leaving an unexposed part.

A heating process is applied after the exposure to form the insulative portion 14 on the upper and lateral surfaces of the auxiliary electrode 13 as shown in FIGS. 5A and 5B. Thus, the organic layer 15 and the auxiliary electrode 13 that are later formed are not in contact with each other.

Though an instance in which the electrically insulative material is provided by a positive photoresist material containing an electrically insulative resin has been described above, a thermosetting resist material containing an electrically insulative resin may alternatively be used. In this instance, it is preferable that the thermosetting resist material is applied so that only the upper and lateral surfaces of the auxiliary electrode 13 are applied with the electrically insulative material with a screen printing. When the thermosetting resist material is applied with the screen printing, it is preferable that the electrically insulative material is printed at the position corresponding to an area at a vertically upper side of the upper and lateral surfaces of the auxiliary electrode 13. In the above arrangement, since a typical thermosetting resist material has a flatness, though a step is provided between an upper part and a lower part of the auxiliary electrode 13, a film is formed so that the lateral part of the auxiliary electrode 13 is completely covered.

Subsequently, as shown in FIG. 6, the organic layer 15 is provided on the auxiliary electrode 13 covered with the insulative portion 14 and on the first electrode 12 exposed through the opening 13C (see FIGS. 5A and 5B). The organic layer 15 may be formed by a known method including dry film-forming such as vacuum deposition, sputtering, plasma deposition and ion plating, and wet film-forming such as spin coating, dipping, flow coating and ink jet printing. At this time, it is preferable that a masking means is applied during layer formation so that the organic layer 15 is formed at predetermined positions.

Subsequently, as shown in FIG. 7, the second electrode 16 is formed on the organic layer 15. At this time, while the second electrode 16 is kept from being in contact with the leading-assist electrode 13A so as not to be electrically connected, the second electrode 16 is in contact with the leading-assist electrode 13B to be electrically connected. The second electrode 16 may be formed by a known method such as vacuum deposition and sputtering. At this time, it is preferable that the second electrode 16 is formed at predetermined positions by mask sputtering and the like.

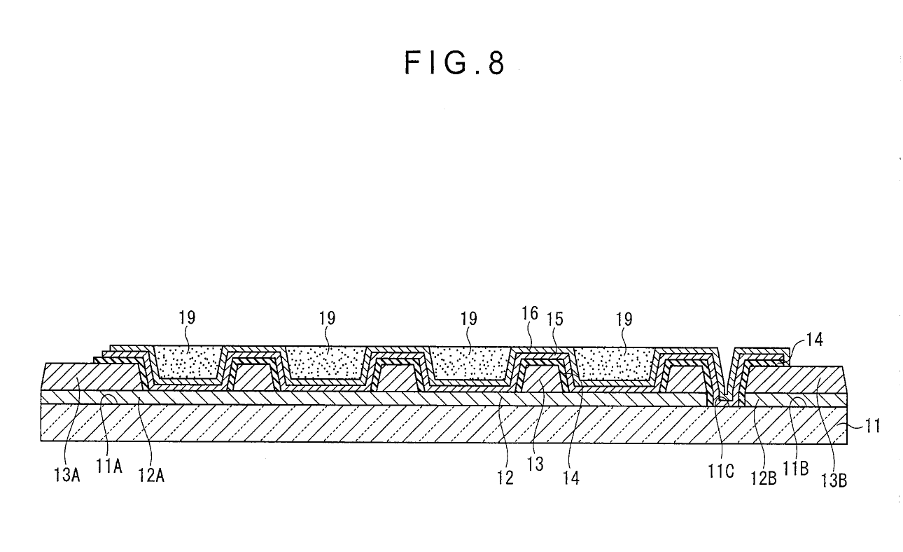

Further, as shown in FIG. 8, the fluid heat-radiation member 19 is injected to an inside of the opening 13C of the frame-shaped auxiliary electrode 13 so that the heat-radiation member 19 is not flowed out of the frame.

### Production Step of Second Substrate Component

Next, the production step on the side of the second substrate 17 will be described below. In the production step, a fritted glass is used as the sealing member 18.

Initially, the sealing member 18 is applied on a surface of the second substrate 17 to be bonded with the first substrate 11. At this time, the sealing member 18 is applied along the outer periphery of the second substrate 17. The sealing member 18 is applied in a width capable of ensuring the bonding strength. The sealing member 18 is applied by, for instance, using a dispenser.

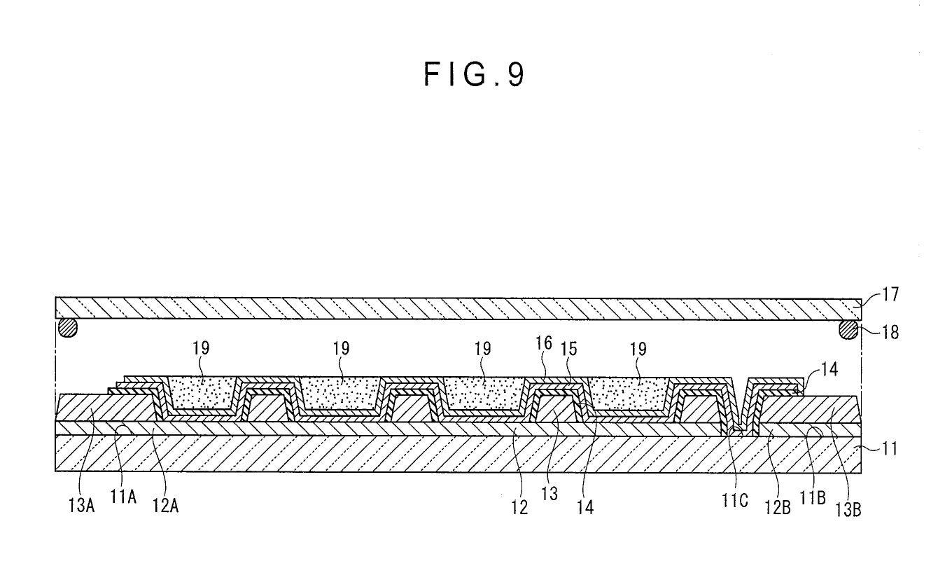

Incidentally, FIG. 9 shows the sealing member 18 applied on a lower side of the second substrate 17 because FIG. 9 illustrates the first substrate 11 and the second substrate 17 to be bonded with each other. Accordingly, in an actual production process of the second substrate 17, the sealing member 18 is applied on an upper surface of the second substrate 17.

The sealing member 18 used in the production step is a paste when being applied and contains an organic solvent. Thus, the organic solvent has to be removed.

Accordingly, a heater such as a hot plate is disposed on the other one of the surfaces of the second substrate 17 opposite to the surface on which the sealing member 18 is applied and the second substrate 17 is heated through the opposite surface to be subjected to a baking treatment. The baking treatment removes the alcohol component. Incidentally, the heating may alternatively be conducted by putting the second substrate 17 in a heating furnace.

### Adhesion Step

As shown in FIG. 9, the surface of the first substrate 11 (pointing upward) on which the first electrode 12 and the like are provided is adhered to the surface of the second substrate 17 (pointing downward) on which the sealing member 18 is formed in alignment with a predetermined bonding portion. During the adhesion, a positioning jig and the like may be used for bonding at an accurate position.

Subsequently, while the second substrate 17 is placed upward, laser is irradiated on the portion at which the sealing member 18 is applied to locally heat the portion. The heating melts the sealing member 18 and bonds the sealing member 18 and the member in contact with the sealing member 18 (e.g. the first substrate 11) to seal the organic layer 15. When the sealing member 18 is bonded, the laser output and laser movement speed are adjusted using a radiation thermometer so that the temperature of the sealing member 18 becomes 600 degrees C.

The photoelectric conversion device 1 is produced as described above.

According to the above-described first exemplary embodiment, the following advantages can be obtained.

(1) The thickness of the auxiliary electrode 13 is greater than the thickness of the organic layer 15 in the cross section of the photoelectric conversion device 1 taken in the thickness direction of the first substrate 11. Thus, the second substrate 17 is supported by the frame-shaped auxiliary electrode 13 provided on the first electrode 12. In other words, since the auxiliary electrode 13 is interposed between the first electrode 12 and the organic layer 15, the auxiliary electrode 13 not only serves as a typical auxiliary electrode but also as a spacer for keeping the distance between the first substrate 11 and the second substrate 17. A recess for accommodating a photoelectric conversion element used in a typical sealing structure is not necessary to be provided to the first substrate 11 and the second substrate 17 of the photoelectric conversion device 1. Specifically, since the second substrate 17 is not in contact with the emitting portion of the organic layer 15, the photoelectric conversion element can be sealed without crushing the organic layer 15. Accordingly, the photoelectric conversion device 1 can safely and hermetically accommodate a photoelectric conversion without relying on a typical sealing structure and the thickness of the photoelectric conversion device 1 can be reduced as compared with the typical arrangement.

(2) Since it is not necessary for the first substrate 11 and the second substrate 17 to have the recess, the photoelectric conversion device 1 can be inexpensively produced.

(3) It is not necessary for the first substrate 11 of the photoelectric conversion device 1 to have an area for providing a rib, a spacer or the like in addition to the area on which the organic layer 15 is formed. Accordingly, a wide area for providing the organic layer 15 can be ensured. Thus, the luminous area can be enlarged.

(4) In the emitting portion 15A, since the second electrode 16 is spaced apart from the second substrate 17, the auxiliary electrode 13 reliably serves as a spacer, thereby keeping the second substrate 17 from contacting the second electrode 16 at the emitting portion 15A. Thus the damage on the second electrode 16 and the organic layer 15 can be avoided.

(5) Since the second electrode 16 is in contact with the second substrate 17 at the non-emitting portion 15B to support the second substrate 17, the distance between the first substrate 11 and the second substrate 17 can be maintained. When the first substrate and the second substrate are adhered, the second substrate is supported by the second electrode, the adhesion process can be facilitated while keeping the distance between the first substrate and the second substrate.

(6) The auxiliary electrode 13 is provided in a frame shape. Accordingly, the fluid heat-radiation member 19 is kept from being flowing out of the frame after being injected in the frame. Thus, the heat-radiation member 19 is kept from flowing to the bonding portion between the first substrate 11 and the second substrate 17 and from further flowing outside the photoelectric conversion device 1.

(7) While the auxiliary electrode 13 is electrically connected with the first electrode 12, the auxiliary electrode 13 is electrically insulated with the organic layer 15 by the presence of the insulative portion 14. Since the organic layer 15 around the frame portion of the auxiliary electrode 13 preferentially emits light, linear light emission may occur without the electrical insulation. However, with the electrical insulation, since the organic layer 15 corresponding to the first electrode 12 emits light, the emitting portion 15A can emit light in a sheet shape.

(8) The sealing member 18 provided by a fritted glass bonds the first substrate 11 and the second substrate 17 to seal the organic layer 15. Accordingly, even when the bonding width is narrow, the photoelectric conversion device 1 of a narrow bezel structure with excellent bonding strength and sealing performance can be obtained.

### Second Exemplary Embodiment

Next, a second exemplary embodiment of the invention will be described below with reference to the attached drawings.

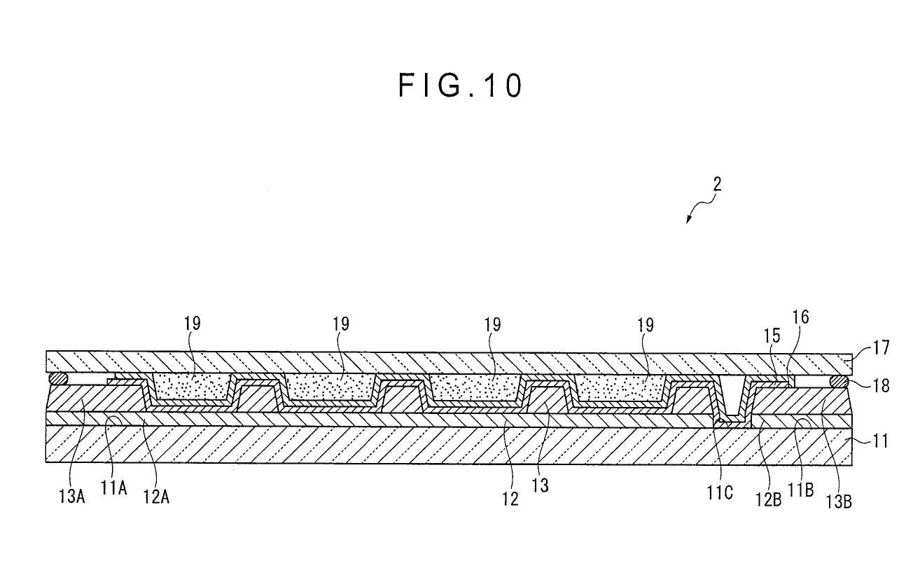

As shown in FIG. 10, a photoelectric conversion device 2 according to the second exemplary embodiment is similar to the photoelectric conversion device 1 according to the first exemplary embodiment except that the insulative portion is not interposed between the auxiliary electrode 13 and the organic layer 15. In the description of the second exemplary embodiment, the same components as those in the first exemplary embodiment are denoted by the same reference signs to simplify or omit an explanation of the components.

In the photoelectric conversion device 2, the organic layer 15 around the area in which the auxiliary electrode 13 is provided tends to preferentially cause light emission. Accordingly, by narrowing the intervals between the lines defining the frame of the auxiliary electrode 13, the luminous areas can be made closer to each other, so that the emitting portion can cause a sheet-shape light emission.

According to the second exemplary embodiment, the following advantage can be obtained in addition to the advantages similar to (1) to (6) and (8) in the first exemplary embodiment.

(9) Since it is not necessary to provide the insulative portion, the photoelectric conversion device 2 can be produced in a simpler process as compared with that for the photoelectric conversion device 1.

### Third Exemplary Embodiment

Next, a third exemplary embodiment of the invention will be described below with reference to the attached drawings.

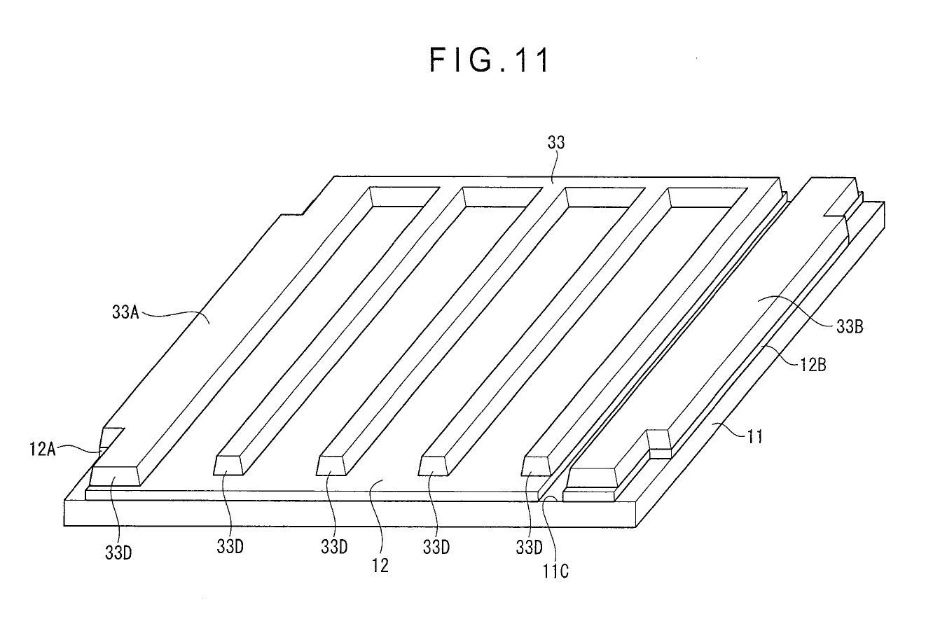

As shown in FIG. 11, a photoelectric conversion device according to the third exemplary embodiment is similar to the photoelectric conversion device 1 according to the first exemplary embodiment except that the shape of the auxiliary electrode 13 is different from that of the auxiliary electrode 13 in the first exemplary embodiment. In the description of the third exemplary embodiment, the same components as those in the first exemplary embodiment are denoted by the same reference signs to simplify or omit an explanation of the components.

In the photoelectric conversion device according to the third exemplary embodiment, the auxiliary electrode pattern provided by an auxiliary electrode 33 is not in the frame shape as in the auxiliary electrode 13 according to the first exemplary embodiment but is in the shape of an end of a fork. Specifically, a plurality of lines of the auxiliary electrode 33 extend substantially in parallel from one side of the first substrate 11 toward an opposite side. An end 33D of the line of the auxiliary electrode 33 is not connected to the end 33D of the adjacent line of the auxiliary electrode 33. In other words, the auxiliary electrode pattern does not define areas closed relative to the second electrode 16 as in the four frames of the auxiliary electrode 13 but is opened at each of the ends 33D.

When the heat-radiation member is to be injected between the second electrode 16 and the second substrate 17 in the photoelectric conversion device according to the third exemplary embodiment, a paste material with a high viscosity may be employed or a bank (not shown) independent of the auxiliary electrode 33 may be provided so that the heat-radiation member does not flow out. The bank may be provided so that the heat-radiation member does not reach the bonding portion between the first substrate 11 and the second substrate 17. For instance, the bank is provided to connect the ends 33D of the lines to close the open portions of the auxiliary electrode 33. However, the thickness of the bank is defined so that the upper surface of the bank is not in contact with the second electrode 16.

In the third exemplary embodiment, similarly to the first exemplary embodiment, a leading-assist electrode 33A for electrical output from the first electrode 12 (anode) is provided on the leading electrode 12A. Further, a leading-assist electrode 33B for electrical output from the second electrode 16 (cathode) is provided on the leading electrode 12B. The leading-assist electrode 33A is continuous with the auxiliary electrode 33, whereas the leading-assist electrode 33B is discontinuous with the auxiliary electrode 33 with the groove 11C interposed therebetween. The leading-assist electrode 33B is not electrically connected with the auxiliary electrode 33 and the first electrode 12.

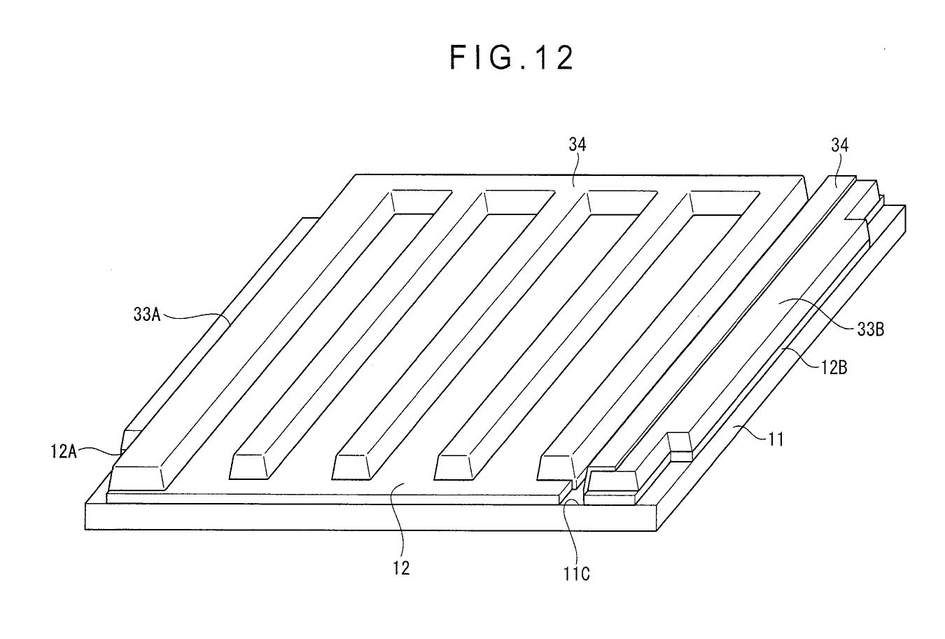

In the third exemplary embodiment, as shown in FIG. 12, an insulative portion 34 is provided on the auxiliary electrode 33 in the same manner as in the first exemplary embodiment. The ends 33D of the lines of the auxiliary electrode 33 is also covered with the insulative portion 34 to electrically insulate the organic layer 15 from the auxiliary electrode 33.

According to the third exemplary embodiment, the following advantage can be obtained in addition to the advantages (1) to (5), (7) and (8) in the first exemplary embodiment.

(10) The auxiliary electrode pattern of the auxiliary electrode 33 is defined so that the ends are opened instead of the closed areas defined by the four frames of the auxiliary electrode 13. Accordingly, even when the second electrode 16 is disconnected along the auxiliary electrode pattern of the auxiliary electrode 33 while the photoelectric conversion device is used for an application requiring flexibility and is repeatedly bent, a non-conductive portion is not formed on the second electrode 16 and an electrical conduction is ensured through the open portions. Thus, a non-emitting portion can be kept from being generated for a long time.

On the contrary, supposing that the auxiliary electrode pattern of the auxiliary electrode 13 defines a frame shape to provide the closed areas, when the second electrode 16 is disconnected along the frame after repeated bending, a frame-shaped disconnected section is created on the surface of the second electrode 16. In this case, since a non-conductive section is defined within the frame, it is possible that the organic layer 15 at the area corresponding to the non-conductive section does not emit light. However, by providing the second substrate 17 with a metal, since the area within the frame can be made conductive through the second substrate 17, so that the organic layer 15 can emit light even when the second electrode 16 is disconnected along the frame.

### Modifications

It should be noted that the invention is not limited to the above exemplary embodiments but may include the following modifications as long as such modifications are compatible with an object of the invention.

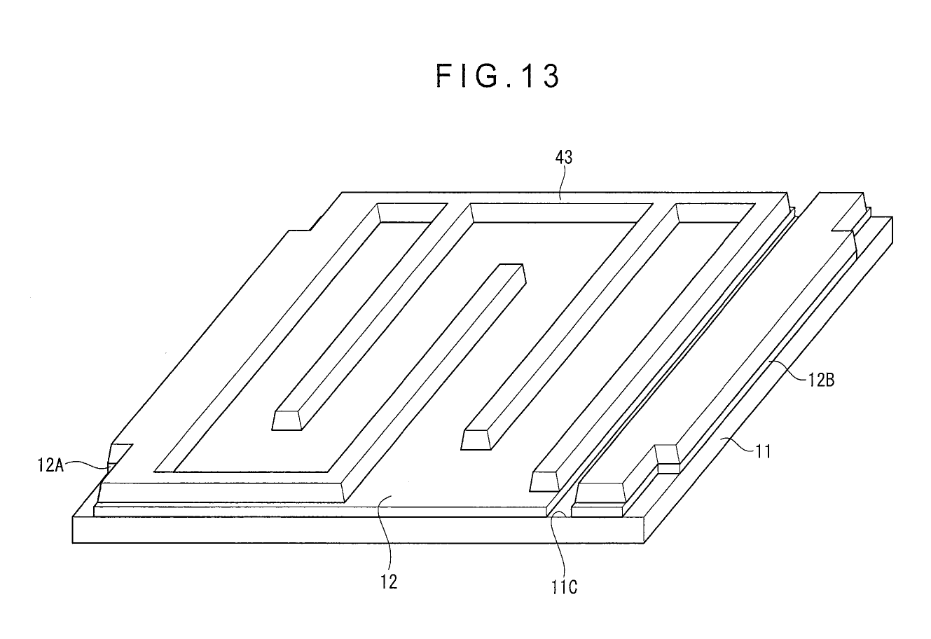

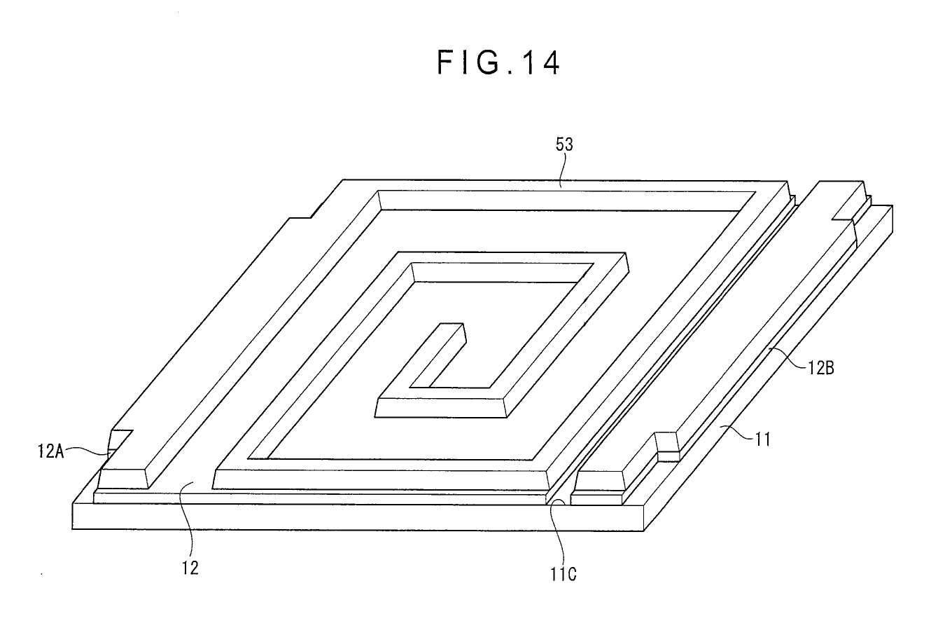

The auxiliary electrode pattern of the auxiliary electrode 33 in the third exemplary embodiment may be differently arranged in a comb-toothed pattern of an auxiliary electrode 43 shown in FIG. 13 or, alternatively, in a spiral auxiliary electrode pattern of an auxiliary electrode 53 shown in FIG. 14. Both of the patterns provide no closed areas but a part thereof is opened. In the description of FIGS. 13 and 14, the same components as those in the first exemplary embodiment are denoted by the same reference signs to simplify or omit an explanation of the components.

Other than the above, the auxiliary electrode may be patterned so as to provide a web, stripe of linear or curved line or a comb-shaped arrangement of lines. Further alternatively, the auxiliary electrode may be provided by line patterns regularly combining geometric line patterns including triangle (e.g. regular triangle, isosceles triangle and right triangle), tetragon (e.g. square, rectangle, rhombus, parallelogram and trapezoid), polygon (e.g. hexagon and octagon), circle, ellipsoid, star shape, honeycomb shape and the like. Still further alternatively, the auxiliary electrode may be provided by an irregular shape or irregular pattern.

When the light is extracted though a side of the second substrate 17 opposite to the first substrate 11 in the photoelectric conversion device 1 according to the first exemplary embodiment, the first substrate 11 may be provided by an opaque substrate such as a silicon substrate and metal substrate in addition to the light-transmissive first substrate 11.

Further, instead of separately producing the photoelectric conversion device 1 as in the production process described in the first exemplary embodiment, a plurality of the photoelectric conversion devices 1 may be produced in one process.

For instance, when the photoelectric conversion device of 80 mm×80 mm is produced from a single first substrate of 470 mm×370 mm, considering the space between each of the photoelectric conversion devices, twenty pieces of the photoelectric conversion device 1 can be produced.

The production process as mentioned above can be performed, for instance, as follows.

The layers are sequentially formed from the first electrode on the first substrate as described in the first exemplary embodiment, and the second substrate having the same size as the first substrate is attached to be bonded to the first substrate under a reduced pressure atmosphere. Subsequently, the attached substrates are cut in an atmospheric pressure with a laser irradiation to obtain each of the photoelectric conversion devices 1.

The photoelectric conversion element used for the photoelectric conversion device is exemplified by the organic EL device in the above exemplary embodiments. However, the invention is applicable not only to the organic EL device but also to any devices such as an organic thin-film solar cell element and a dye-sensitised solar cell that are required to be airproof. Such solar cell elements can reduce the thickness thereof without reducing a light-receiving area and can be inexpensively produced.

The organic thin-film solar cell element may be provided by sequentially layering a transparent conductive film, a P-type organic semiconductor, an N-type organic semiconductor and a conductive film on the first substrate 11 (light incident face). The transparent conductive film may be provided by a transparent electrode member so that the light through the first substrate 11 reaches a solar cell layer (the P-type organic semiconductor and the N-type organic semiconductor). For instance, a transparent electrode made of ITO (indium tin oxide), ZnO (zinc oxide), SnO₂ (tin oxide) and the like is usable.

The conductive film may be provided as a less light-absorptive and highly reflective metal electrode such as aluminum, gold, silver and titanium that is suitable as a reflective film. Alternatively, a multilayered electrode of the above metals, or a multilayered electrode with layers of the above metals, other metals, conductive oxides (e.g. the above materials for the transparent electrode) and conductive organic compounds may be used as the reflective film. The rest of the components may be the same as those in the exemplary embodiments.

Though the heat-radiation member 19 in the above exemplary embodiments has a fluidity, a heat-radiation member without fluidity may be used as long as the heat-radiation member can be provided between the second substrate 17 and the second electrode 16 so that the heat generated in the organic layer 15 is transferrable to the second substrate 17.

Alternatively, without providing the heat-radiation member 19, inactive gas may be filled between the second substrate 17 and the second electrode 16.

### INDUSTRIAL APPLICABILITY

The photoelectric conversion device according to the invention provides a large light-emitting area and a small thickness. Thus, the photoelectric conversion device is applicable not only to an ordinary organic EL device and an organic thin-film solar cell but also as a flexible organic EL illumination device and a flexible solar cell.

### EXPLANATION OF CODES

1, 2 . . . photoelectric conversion device
11 . . . first substrate
12 . . . first electrode
13, 33, 43, 53 . . . auxiliary electrode
14, 34 . . . insulative portion
15 . . . organic layer
15A . . . emitting portion
16 . . . second electrode
17 . . . second substrate
18 . . . sealing member
19 . . . heat-radiation member

1. A photoelectric conversion device comprising:
a first substrate;
a first electrode;
an organic layer;
a second electrode; and
a second substrate, layered in this order; and
an auxiliary electrode interposed at a non-emitting portion between the first electrode and the organic layer, wherein
a thickness of the auxiliary electrode is greater than a thickness of the organic layer in a cross section of the photoelectric conversion device taken in a thickness direction of the first substrate.

2. The photoelectric conversion device according to claim 1, wherein the second electrode is in contact with the second substrate.

3. The photoelectric conversion device according to claim 1, wherein
a sealing member, which seals the organic layer, is interposed between the first substrate and the second substrate along an outer periphery of the first substrate and the second substrate, and
the thickness of the auxiliary electrode and a thickness of the sealing member satisfies formula (I):
0.2X<Y<5X (1)
wherein Y represents the thickness of the auxiliary electrode and X represents the thickness of the sealing member.

4. The photoelectric conversion device according to claim 1, wherein the thickness of the auxiliary electrode is in a range from 0.5 μm to 30 μm.

5. The photoelectric conversion device according to claim 3, wherein the sealing member comprises an insulative material.

6. The photoelectric conversion device according to claim 1, wherein
an area interposed between the first electrode and the second electrode where the auxiliary electrode is not disposed defines an emitting portion in which the organic layer is disposed, and
the second electrode is spaced apart from the second substrate at the emitting portion.

7. The photoelectric conversion device according to claim 6, wherein a heat-radiation member is interposed between the second electrode and the second substrate at the emitting portion.

8. The photoelectric conversion device according to claim 7, wherein the auxiliary electrode defines a frame shape surrounding the emitting portion when the photoelectric conversion device is seen facing a surface of the first substrate.

9. The photoelectric conversion device according to claim 6, wherein the auxiliary electrode defines a shape surrounding the emitting portion with a part thereof being opened when the photoelectric conversion device is seen facing a surface of the first substrate.

10. The photoelectric conversion device according to claim 1, wherein an electrically conductive path exists between the auxiliary electrode and the first electrode while the auxiliary electrode is electrically insulated from the organic layer.

11. The photoelectric conversion device according to claim 10, wherein an insulative portion is interposed between the auxiliary electrode and the organic layer.

12. The photoelectric conversion device according to claim 11, wherein the insulative portion comprises a polyimide.

13. The photoelectric conversion device according to claim 1, wherein the auxiliary electrode comprises a resin and at least one selected from the group consisting of silver, gold, tungsten and neodymium.

14. The photoelectric conversion device according to claim 1, wherein
the first substrate is light-transmissive, and
the first electrode is transparent.

15. The photoelectric conversion device according to claim 1, wherein the second substrate comprises a metal.

16. A method of producing the photoelectric conversion device of claim 1, the photoelectric conversion device comprising: a first substrate; a first electrode; an organic layer; a second electrode; and a second substrate, the first substrate, the first electrode, the organic layer, the second electrode and the second substrate being layered in this order, the method comprising:
forming the first electrode on one surface of the first substrate;
forming the auxiliary electrode at an area to be a non-emitting portion on the first electrode;
forming the organic layer on the first electrode and the auxiliary electrode;
forming the second electrode on the organic layer; and
after the second electrode is formed, attaching and bonding the first substrate and the second substrate, wherein
a thickness of the auxiliary electrode is formed greater than a thickness of the organic layer in a cross section of the photoelectric conversion device taken in a thickness direction of the first substrate.

17. The method according to claim 16, wherein
in the forming of the auxiliary electrode, the auxiliary electrode is formed in a frame shape seen in a direction facing a surface of the first substrate, and
after forming the second electrode and before attaching and bonding the first substrate and the second substrate, a fluid heat-radiation member is injected into the frame defined by the auxiliary electrode.

18. The method according to claim 16, wherein
after forming the auxiliary electrode and before forming the organic layer, an insulative portion is formed on the auxiliary electrode, and
the insulative portion is interposed between the organic layer and the auxiliary electrode.

19. The photoelectric conversion device according to claim 2, wherein
a sealing member, which seals the organic layer, is interposed between the first substrate and the second substrate along an outer periphery of the first substrate and the second substrate, and
the thickness of the auxiliary electrode and a thickness of the sealing member satisfies formula (I):
0.2X≦Y≦5X (1)
wherein Y represents the thickness of the auxiliary electrode and X represents the thickness of the sealing member.

20. The photoelectric conversion device according to claim 2, wherein the thickness of the auxiliary electrode is in a range from 0.5 μm to 30 μm.
